(19) United States
(12) Patent Application Publication
(10) Pub. No.: US 2023/0420913 A1
(43) Pub. Date: Dec. 28, 2023

(54) OPTOELECTRONIC COMPONENT AND METHOD FOR PRODUCING AN OPTOELECTRONIC COMPONENT

(71) Applicant: ams-OSRAM International GmbH, Regensburg (DE)

(72) Inventor: Jörg Erich Sorg, Regensburg (DE)

(73) Assignee: ams-OSRAM International GmbH, Regensburg (DE)

(21) Appl. No.: 18/249,307

(22) PCT Filed: Oct. 12, 2021
(86) PCT No.: PCT/EP2021/078183

§ 371 Date: Apr. 17, 2023

(30) Foreign Application Priority Data
Oct. 19, 2020 (DE) 10 2020 127 450.5

(51) Int. Cl. H01S 5/028; H01L 33/44; H01L 33/00

(52) U.S. Cl. CPC H01S 5/0283; H01L 33/44; H01L 33/0095; H01S 5/183

(57) ABSTRACT

The invention relates to an optoelectronic component including a semiconductor chip having a coupling-out facet that emits electromagnetic primary radiation during operation, —a functional layer, wherein the coupling-out facet is at least partially covered by the functional layer, and —the functional layer is a catalytic layer. The invention also relates to a method for producing an optoelectronic component.

### CROSS-REFERENCE TO RELATED APPLICATIONS

The present application is a national stage entry from International Application No. PCT/EP2021/078183, filed on Oct. 12, 2021, published as International Publication No. WO 2022/084105 A1 on Apr. 28, 2022, and claims priority to German Patent Application No. 10 2020 127 450.5, filed Oct. 19, 2020, the disclosures of all of which are hereby incorporated by reference in their entireties.

### FIELD OF THE INVENTION

An optoelectronic component is specified. In addition, a method for producing an optoelectronic component is specified.

### BACKGROUND OF THE INVENTION

One problem to be solved is to specify an improved optoelectronic component. Another problem to be solved is to specify a method for producing an optoelectronic component.

An optoelectronic component is specified. Optoelectronic components may comprise at least one semiconductor chip that emits and/or receives electromagnetic radiation in a predetermined wavelength range. For example, the optoelectronic component is a semiconductor laser component or a light-emitting diode.

### SUMMARY OF THE INVENTION

According to at least one embodiment, the optoelectronic component comprises a semiconductor chip. The semiconductor chip is, for example, an optoelectronic semiconductor chip. The optoelectronic semiconductor chip, such as a light emitting diode chip, a photodiode chip, and/or a laser diode chip, comprises an epitaxially grown semiconductor layer sequence with an active region configured to detect or generate electromagnetic radiation. During operation, the semiconductor chip can emit and/or receive electromagnetic radiation from a wavelength range of UV radiation, blue light and/or in the infrared range, for example.

The semiconductor chip may comprise various semiconductor materials based on, for example, a III-V semiconductor material system.

According to at least one embodiment, the semiconductor chip of the optoelectronic component comprises a coupling-out facet that emits electromagnetic primary radiation during operation. For example, a side surface of the semiconductor chip serves at least in places as coupling-out facet. The coupling-out facet may be oriented transversely, preferably perpendicularly, to a main extension plane of the active region. The region where the electromagnetic primary radiation exits is in particular a subregion of the coupling-out facet.

In particular, a large portion of the electromagnetic primary radiation emitted by the semiconductor chip during operation exits the semiconductor chip at the coupling-out facet. This may mean that at least 90% of the electromagnetic primary radiation emitted by the semiconductor chip during operation exits the semiconductor chip at the coupling-out facet. The proportion of the electromagnetic primary radiation emitted by the semiconductor chip during operation which exits the semiconductor chip at the coupling-out facet is greater than the proportion which exits the semiconductor chip at other places.

According to at least one further embodiment, the optoelectronic component comprises a functional layer, wherein the coupling-out facet is covered by the functional layer at least in places. The coupling-out facet may be completely or in places covered by the functional layer. Preferably, at least the subregion of the coupling-out facet is covered by the functional layer. The functional layer may be applied as a layer and/or as a film.

Furthermore, the functional layer can be applied directly to the coupling-out facet. Alternatively, an adhesive layer can be arranged between the functional layer and the coupling-out facet. In particular, the functional layer may comprise a round or an angular shape. In particular, the functional layer may comprise multiple layers. In this regard, the multiple layers may comprise different materials.

According to at least one embodiment, the functional layer is a catalytic layer. The catalytic layer comprises at least one catalyst. The catalyst is configured to shift a reaction equilibrium. Catalysts increase the reaction rate of a chemical reaction by lowering the activation energy without being consumed themselves. In particular, the functional layer is configured to comprise a catalytic activity. In particular, the catalytic layer permanently catalyzes a chemical reaction during operation of the optoelectronic component.

According to at least one embodiment, the optoelectronic component comprises a semiconductor chip comprising an coupling-out facet that emits electromagnetic primary radiation during operation and a functional layer, wherein the coupling-out facet is covered by the functional layer at least in places and the functional layer is a catalytic layer.

According to at least one embodiment, the functional layer is configured to shift a reaction equilibrium from volatile molecules to solid compounds to the side of volatile molecules.

Highly volatile molecules are, for example, nitrogen, nitrogen oxides, oxygen, water vapor, carbon monoxide, carbon dioxide, molecules with a low molecular weight, such as highly volatile hydrocarbon compounds, or silicon compounds, such as organosilicon compounds. Highly volatile hydrocarbon compounds are, for example, carbon rings or carbon chains, such as alkanes, which change into the gas phase by evaporation at room temperature or higher temperatures. In particular, highly volatile molecules do not settle on the coupling-out facet.

Solid compounds are in particular robust, inert compounds that are not volatile. For example, solid compounds are elemental carbon, SiO₂ and long-chain carbon compounds or silicon compounds, which are not volatile. In particular, the solid compound settles on the coupling-out facet.

The reaction equilibrium is established between the volatile molecules and the solid compounds. Due to the functional layer the reaction equilibrium is in particular shifted to the side of the volatile molecules. Thus, the coupling-out facet is with advantage free of solid compounds. This means that overheating and thus damage to the semiconductor chip is reduced with advantage.

The electromagnetic primary radiation emitted by the coupling-out facet during operation causes radicals to form. The electromagnetic primary radiation hits particles or molecules in the environment and splits them to form radicals. The radicals are in particular atoms or molecules with at least one unpaired valence electron. Radicals are particularly reactive and can be formed by UV radiation, heat, X-ray and other ionizing radiation or electrochemically by oxidation or reduction.

In particular, radicals recombine and settle as a solid compound on the coupling-out facet of the semiconductor chip due to the optical tweezer effect and lead there to overheating of the semiconductor chip. This can then lead to destruction or damage of the semiconductor chip. Due to the functional layer the problem of overheating can be reduced. The solid compounds react at the coupling-out facet to form the volatile molecules and settling at the coupling-out facet is thereby reduced with advantage. Overheating of the semiconductor chip is minimized by the functional layer. With other words, the functional layer allows the reaction equilibrium between absorption and desorption to be shifted toward desorption. That is, the reaction equilibrium at the coupling-out facet is specifically shifted toward the reactant side. For this purpose, the reactant side represents the volatile molecules, which in particular do not settle on the coupling-out facet.

According to at least one embodiment, the volatile molecules are gaseous. In particular, the volatile molecules are organic molecules.

According to at least one embodiment, the functional layer comprises or consists of a polyoxometalate. For example, the polyoxometalate is embedded in a transparent matrix material, for example a polysiloxane.

Polyoxometallates have polyatomic anions. These are composed of three or more transition metal oxyanions and bridged via oxygen atoms. Thus, a large closed three-dimensional network can be formed. The metal atoms are usually transition metals of groups V or VI in high oxidation numbers. Examples are vanadium, niobium, tantalum, molybdenum and tungsten.

The polyoxometallates can be divided into two groups. Heteropolyanions and isopolyanions. Heteropolyanions are metal clusters with included heteroanions such as the sulfate ion or the phosphate ion. Isopolyanions are pure metal oxide networks without heteroatoms. Polyoxometallates comprise the advantage of being inexpensive.

According to at least one embodiment, the functional layer comprises a metal compound or consists of a metal compound. In particular, the functional layer comprises a metal oxide. The metal compound is embedded in a transparent matrix material, for example in a polysiloxane.

In particular, the metal compound is selected from the following group: TiO₂, SiO₂, ZrO₂, Al₂O₃, MgF₂, YAG, In₂O₃—SnO₂, SnO₂, Y₂O₂, Ta₂O₂, Nb₂O₃ or combinations thereof. By using metal compounds as a functional layer, the emitted electromagnetic primary radiation can be optically refracted. In particular, the metal compounds comprise a refractive index greater than 1.3. Table 1 shows the refractive indices of the individual metal compounds at the corresponding wavelengths.

TABLE 1
Refractive indices of the metal compounds
at the corresponding wavelength.

| Metal compound | Refractive index | Wavelength [μm] |
|---|---|---|
| MgF₂ | 1.3777 | 0.5876 |
| SiO₂ | 1.4585 | 0.5876 |
| Al₂O₃ - Sapphire | 1.7700 | 0.5876 |
| YAG/second phase | 1.8000 | — |
| In₂O₃—SnO₂ | 1.8270 | 0.5876 |
| SnO₂ | 1.8300 | — |
| Y₂O₃ | 1.9307 | 0.5876 |
| Ta₂O₅ | 2.1462 | 0.5876 |
| ZrO₂ | 2.1588 | 0.5876 |
| Nb₂O₃ | 2.3403 | 0.5876 |

According to at least one embodiment, the functional layer comprises a polyoxometalate in which at least one metal compound is embedded.

According to at least one embodiment, the functional layer is selected from the group consisting of:
platinum, vanadium, molybdenum, titanium, tungsten, tantalum, palladium and FeN₄ complexes. In particular, the functional layer is formed as a film.

It is also possible that several functional layers with different materials are applied to the coupling-out facet.

According to at least one embodiment, the functional layer is selected from the group consisting of: platinum, vanadium, molybdenum, titanium, tungsten, tantalum, palladium and FeN₄ complexes and additionally comprises at least one metal compound.

According to at least one embodiment, the coupling-out facet is completely covered by the functional layer. That is, the electromagnetic primary radiation emitted by the coupling-out facet is completely covered by the functional layer.

According to at least one embodiment, a thickness of the functional layer is at most 10 micrometers, preferably at most 5 micrometers. In particular, the functional layer is dense. That is, no compounds can penetrate through it. The functional layer may further comprise optical quality. With other words, the functional layer is transparent, non-absorbing, and non-scattering. For example, the functional layer comprises a transparency for primary radiation of at least 95%, in particular at least 98%. Preferably, the functional layer does not comprise scattering particles or phosphor particles. In other words, the functional layer is free of scattering particles and free of phosphor particles.

According to at least one embodiment, the functional layer comprises a uniform thickness. In other words, the thickness of the functional layer varies around a mean value with a maximum deviation of 5%.

According to at least one embodiment, the semiconductor chip comprises an active region and a waveguide each adjacent to the coupling-out facet, and at least the active region and/or the waveguide is completely covered by the functional layer at the coupling-out facet.

The waveguide is an inhomogeneous medium which, by its physical nature, focuses the electromagnetic primary radiation so that it is guided as a travelling wave. That is, the region of the coupling-out facet where the active region and/or the waveguide is located is completely covered by the functional layer. The functional layer here comprises a round shape in particular.

According to at least one embodiment, the functional layer is in direct contact with the coupling-out facet. That is, preferably no additional layer is arranged between the coupling-out facet and the functional layer. The functional layer can thus be formed directly on the coupling-out facet.

According to at least one embodiment, the functional layer comprises a thickness of at most 5000 nanometers. In particular, the functional layer comprises a thickness of at most 2000 nm. Preferably, the functional layer comprises a thickness of at most 100 nanometers. The thickness of the functional layer is thus selected such that an absorption of the electromagnetic primary radiation by the functional layer is less than 20%, in particular less than 10%, relative to the power of the emitted radiation. At the same time, the thickness is sufficiently large to ensure the catalytic activity of the functional layer. In particular, the functional layer is thick enough so that the reaction equilibrium between absorption and desorption is on the side of desorption. A too thin thickness of the functional layer, for example in the order of the wavelength, can lead to side effects.

According to at least one embodiment, the functional layer is formed as a monolayer. A monolayer is a layer of atoms, molecules or cells on a surface, wherein the layer height is only one atom, one molecule or one cell. Accordingly, no identical atoms or molecules lie on top of each other in the monolayer. In particular, the monolayer comprises a thickness of less than or equal to 5 nanometers. For example, the monolayer comprises a thickness of less than or equal to 1 nanometer.

According to at least one embodiment, the optoelectronic component is an edge-emitting semiconductor laser component.

The edge-emitting semiconductor laser component comprises a semiconductor chip configured to emit laser radiation. That is, during operation, the semiconductor chip emits electromagnetic primary radiation, for example, in the wavelength range between IR and UV radiation. In particular, the semiconductor chip is an edge-emitting semiconductor laser chip in which the laser radiation is emitted at an end face, that is, at a facet of the semiconductor chip. That is, the coupling-out facet of the semiconductor chip, through which the generated laser radiation exits from the semiconductor chip during operation, is located at the end face.

Further, the edge-emitting semiconductor laser component includes the functional layer covering the coupling-out facet at least in places.

The coupling-out facet of the edge-emitting semiconductor laser component has high steel divergences. In conjunction with high energy densities, this results in high field strengths. The high field strengths lead to a material transport of molecules and particles to the coupling-out facet (“optical tweezer effect”). The functional layer on the coupling-out facet leads to a reduction in the settling of molecules on the coupling-out facet. Overheating of the optoelectronic component is thus reduced.

In particular, the semiconductor chip comprises a p-up configuration or a p-down configuration. In the p-down configuration, a resonator is located on the bottom side of the semiconductor chip. In the p-up configuration, the resonator is located at the top side of the semiconductor chip. The resonator is an arrangement of two mirrors in which the radiation is repeatedly guided through the area.

According to at least one embodiment, the optoelectronic component is a surface emitter. In particular, the surface emitter is a VCSEL (vertical-cavity surface-emitting laser). Furthermore, the surface emitter is a laser diode in which the electromagnetic primary radiation is emitted perpendicular to the main plane of the semiconductor chip.

According to at least one embodiment, the optoelectronic component is a superluminescent diode. The structure of the superluminescent diode corresponds to the structure of a laser diode but without resonator. The radiation is based on the so-called amplified spontaneous emission and combines the brightness of laser diodes and the low coherence of light-emitting diodes, which is equivalent to a wider optical bandwidth of the emitted radiation.

According to at least one embodiment, the semiconductor chip emits electromagnetic radiation of a wavelength range of less than 500 nanometers during operation. In particular, the semiconductor chip emits electromagnetic radiation of a wavelength range of less than 480 nanometers during operation. For example, during operation, the semiconductor chip emits electromagnetic radiation with a peak wavelength of less than 500 nanometers, preferably less than 480 nanometers. Such a short wavelength range leads increasingly to the decomposition of carbon compounds and the formation of radicals.

According to at least one embodiment, the optoelectronic component is free of a hermetic housing. Hermetic means that the housing is hermetically and impenetrably sealed. That is, the optoelectronic component does not require a hermetically sealed housing. A stable operation of the optoelectronic component is ensured even in a non-hermetic and non-organic environment. Thus, it is not necessary to arrange the semiconductor chip in a larger housing in a cavity and to seal the housing. Therefore, less packaging space is required for the optoelectronic component. This results in low production costs.

According to at least one embodiment, the optoelectronic component comprises a carrier. The carrier may be a three-dimensional body and comprise, for example, the shape of a cylinder, a disk or a cuboid. The carrier may comprise a main extension plane. The main extension plane of the carrier is, for example, parallel to a surface, for example a top surface, of the carrier.

It is possible that the carrier comprises a driver with which the optoelectronic component can be driven. Alternatively, it is possible that the carrier is an electronically passive component and serves only to provide a mounting plane.

The semiconductor chip can be arranged on the cover surface of the carrier. The semiconductor chip can be connected with the carrier via electrical contacts so that the semiconductor chip can be controlled via the carrier. For example, the semiconductor chip comprises electrical contacts on the side facing the cover surface of the carrier, which are electrically connected with the carrier. Alternatively, it is possible for the semiconductor chip to be electrically connected to the carrier via bonding wires. The semiconductor chip may be mechanically attached to the carrier on the cover surface.

According to at least one embodiment, the semiconductor chip is arranged on a step. In particular, the step is arranged on a carrier or is formed by a part of the carrier. The step improves the mechanical stability of the optoelectronic component. The step may be a so-called submount. The step is provided in particular for a semiconductor chip which is present in a p-down configuration.

A method for producing an optoelectronic component is further specified. Preferably, the method described herein can be used to produce the optoelectronic component described herein. That is, all features disclosed for the optoelectronic component are also disclosed for the method for producing an optoelectronic component and vice versa.

According to at least one embodiment of the method for producing an optoelectronic component described herein, the semiconductor chip is provided. The semiconductor chip is placed on a carrier, for example. The carrier serves, among other things, to provide mechanical stability.

According to at least one embodiment, the functional layer is applied to the coupling-out facet at least in places. For example, one to five sides of the semiconductor chip are surrounded with the functional layer. The sixth side of the semiconductor chip, which in particular corresponds to the bottom side, preferably remains free of the functional layer. The bottom side is preferably arranged on a carrier.

Preferably, the functional layer is applied to exactly one side of the semiconductor chip. This is the case if the electromagnetic primary radiation of the semiconductor chip is emitted exactly at this side, i.e. if this side comprises the coupling-out facet.

The functional layer can also be applied exclusively to a subregion of the coupling-out facet. The subregion is the region where the electromagnetic primary radiation exits. The coupling-out facet is then not completely but only partially covered with the functional layer.

According to at least one embodiment, the functional layer is vapor deposited or sputtered on the coupling-out facet or deposited via a chemical vapor deposition, a plasma-enhanced chemical vapor deposition, or via a SAM method.

During the vapor deposition of the functional layer on the coupling-out facet, a starting material is heated by an electric heater to temperatures near the boiling point and then the material vapor is moved to the semiconductor chip, where it condenses into the functional layer.

During applying the functional layer on the coupling-out facet by sputtering, atoms are released from a solid by bombardment with high-energy ions and enter the gas phase. The released atoms are settle on the coupling-out facet to form a porous layer, which can be densified by annealing to form the functional layer.

The functional layer can be applied on the coupling-out facet by means of chemical vapor deposition. Hereby, a solid component is deposited from the gas phase on the heated surface of a substrate as a result of a chemical reaction. The prerequisite for this is that volatile compounds of the layer components exist, which deposit the functional layer at a certain reaction temperature.

During plasma-enhanced chemical vapor deposition, the chemical deposition is supported by a plasma. The plasma can burn directly at the substrate to be coated or in a separate chamber.

In the SAM (self-assembled monolayer) method, the functional layer forms spontaneously when surface-active or organic substances are immersed in a solution or suspension.

One idea of the present optoelectronic component is to shift the reaction equilibrium of absorption and desorption on the coupling-out facet towards desorption, i.e. towards the reactants, towards the highly volatile molecules. The functional layer on the coupling-out facet serves to convert the resulting solid compounds on the coupling-out facet to highly volatile molecules. The combustion of material deposited on the coupling-out facet, for example carbon, is enabled as well as accelerated by the functional layer.

In comparative optoelectronic components, the radicals or carbon compounds recombine at the coupling-out facet in such a way that long, solid, non-volatile compounds, such as alkanes, or elemental carbon or silicon dioxide are formed, which lead to overheating of the semiconductor chip and thus damage the optoelectronic component. Hence, comparative optoelectronic components are encapsulated at high cost in order to ensure stable operation over the long term. The comparative optoelectronic components are operated in a clean, hermetically sealed atmosphere on purely inorganic, gas- and moisture-stable packages, so-called gold boxes.

The functional layer on the coupling-out facet results in simplifying the design of the housing. No hermetic housing is required. This lowers costs and reduces the installation space. In addition, the integration of the optoelectronic components in modules is simplified.

Among other things, the functional layer on the coupling-out facet significantly extends the service life of the optoelectronic component.

### BRIEF DESCRIPTION OF THE DRAWING

Further advantageous embodiments and further developments of the optoelectronic component and of the method for producing an optoelectronic component result from the exemplary embodiments described below in conjunction with the figures.

It shows:

FIG. 1 a scanning electron microscope view of an optoelectronic component,

FIGS. 2 and 5 schematic sectional views of an optoelectronic component according to an exemplary embodiment, respectively,

FIGS. 3, 4, 6, and 7 side views of an optoelectronic component according to an exemplary embodiment, respectively,

FIGS. 8 and 9 each a chemical equilibrium reaction, and

FIG. 10 schematic sectional views of various steps of a method for producing an optoelectronic component according to an exemplary embodiment.

### DETAILED DESCRIPTION

Elements that are identical, similar or have the same effect are marked with the same reference signs in the figures. The figures and the proportions of the elements shown in the figures are not to be regarded as true to scale. Rather, individual elements, in particular layer thicknesses, may be shown exaggeratedly large for better representability and/or understanding.

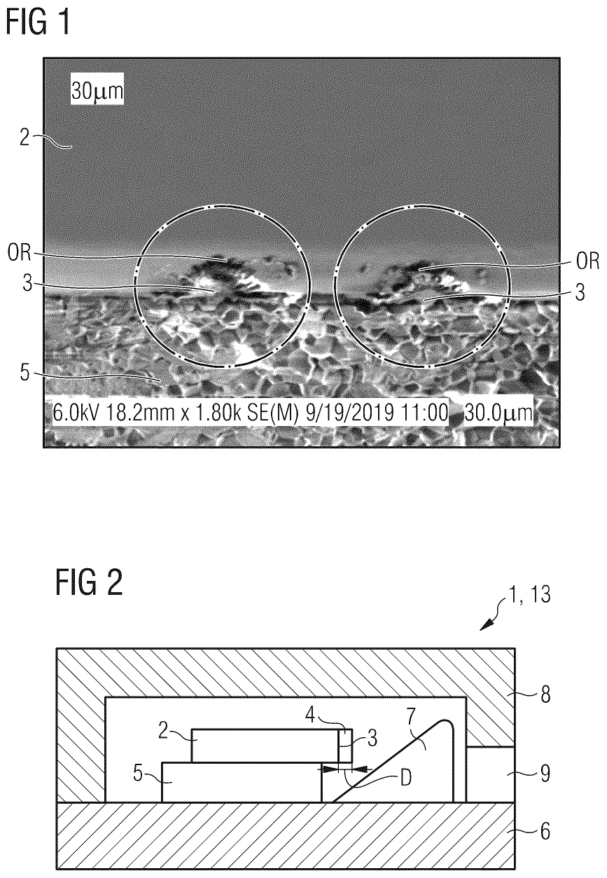

In FIG. 1 a scanning electron microscope image of a comparative optoelectronic component is described. The optoelectronic component comprises a step 5 and a semiconductor chip 2 arranged thereon. The semiconductor chip 2 comprises a coupling-out facet 3 which is oriented perpendicular to a main extension plane of the active region and emits electromagnetic primary radiation during operation. It can be seen that a solid compound OR is deposited on the coupling-out facet. The solid compound OR is, for example, elemental carbon or silicon dioxide. The solid compound OR leads to overheating of the optoelectronic component.

The optoelectronic component 1 according to the exemplary embodiment of FIG. 2 comprises a semiconductor chip 2, comprising a coupling-out facet 3, through which electromagnetic primary radiation is emitted during operation, and a functional layer 4. During operation, the semiconductor chip 2 emits electromagnetic primary radiation of a wavelength range of less than 500 nanometers. Preferably, the wavelength range is smaller than 480 nanometers. In particular, the semiconductor chip 2 emits electromagnetic primary radiation with a peak wavelength of less than 480 nanometers during operation.

The functional layer 4 covers the coupling-out facet 3 at least in places. The functional layer 4 is a catalytic layer.

The semiconductor chip 2 is arranged on a step 5. The step 5 is a so-called submount. The step 5 is in turn arranged on a carrier 6. The semiconductor chip 2 and the step 5 as well as the functional layer 4 are surrounded by a housing 8.

The housing 8 comprises a vent opening 9. The electromagnetic primary radiation emitted from the semiconductor chip 2 strikes an optical element 7 and is deflected thereby. The optical element 7 is configured to shape the emitted electromagnetic primary radiation. The optical element 7 and the vent opening 9 are optionally provided in the optoelectronic component 1.

The functional layer 4 is configured to shift a reaction equilibrium from volatile molecules to solid compounds to the side of volatile molecules. For example, the functional layer 4 is a polyoxometalate. Additionally or alternatively, a metal compound, for example TiO₂, ZrO₂, HfO₂ or SiO₂, can be introduced into the functional layer 4. The coupling-out facet 3 is completely covered by the functional layer 4. The functional layer 4 is in direct contact with the coupling-out facet 3. The functional layer 4 comprises a thickness D of at most 500 nanometers.

The optoelectronic component 1 is an edge-emitting semiconductor laser component 13, that is, the coupling-out facet 3 is located at one end face.

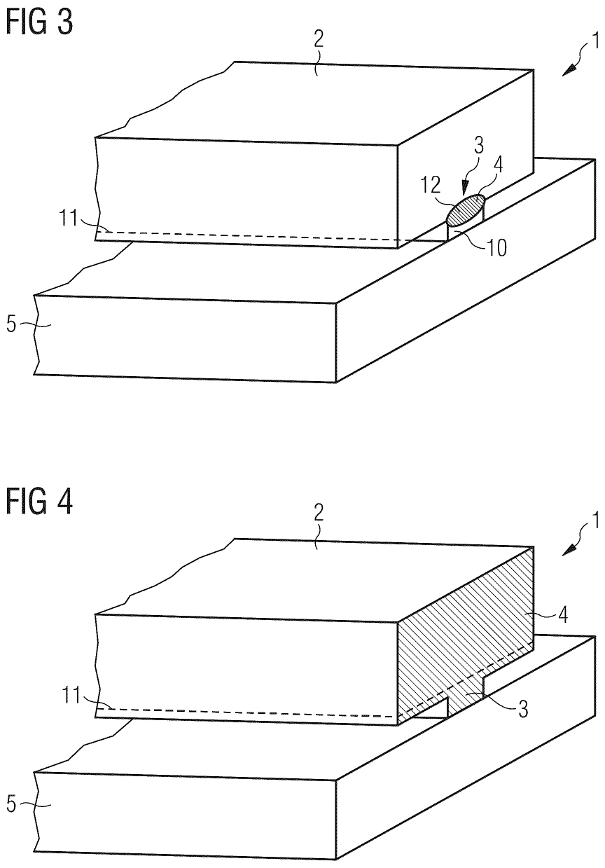

The side view shown in FIG. 3 shows a section in the X direction of an optoelectronic component 1. Here, the optoelectronic component 1 is arranged on a step 5. The step 5 is a so-called submount. The edge-emitting semiconductor laser component 13 comprises a p-down configuration.

A functional layer 4 is arranged on the coupling-out facet 3 of the semiconductor chip 2. The functional layer 4 is arranged on a subregion 12 of the coupling-out facet 3 and comprises a round shape.

The semiconductor chip 2 comprises an active region 11 and a waveguide 10. At least the active region 11 and the waveguide 10 are completely covered by the functional layer 4 at the coupling-out facet 3. The functional layer 4 is also here in direct contact with the coupling-out facet 3 and comprises a polyoxometalate. Alternatively, the functional layer 4 may be selected from the group including platinum, vanadium, molybdenum, titanium, tungsten, tantalum, palladium and FeN₄ complexes. The functional layer 4 may be formed as a film. The functional layer 4 is formed as a monolayer.

The exemplary embodiment shown in FIG. 4 shows an optoelectronic component 1 on a step 5. The optoelectronic component 1 comprises a semiconductor chip 2, a coupling-out facet 3 and a functional layer 4 arranged on the coupling-out facet 3. The functional layer 4 is in direct contact with the coupling-out facet 3 and completely covers the coupling-out facet 3. The optoelectronic component 1 is thereby free of a hermetic housing.

The exemplary embodiment shown in FIG. 5 differs from the exemplary embodiment shown in FIG. 2 in that the semiconductor chip 2 is arranged directly on a carrier 6. In addition, the optoelectronic component 1 can be operated without an optical element 7 and a vent opening 9.

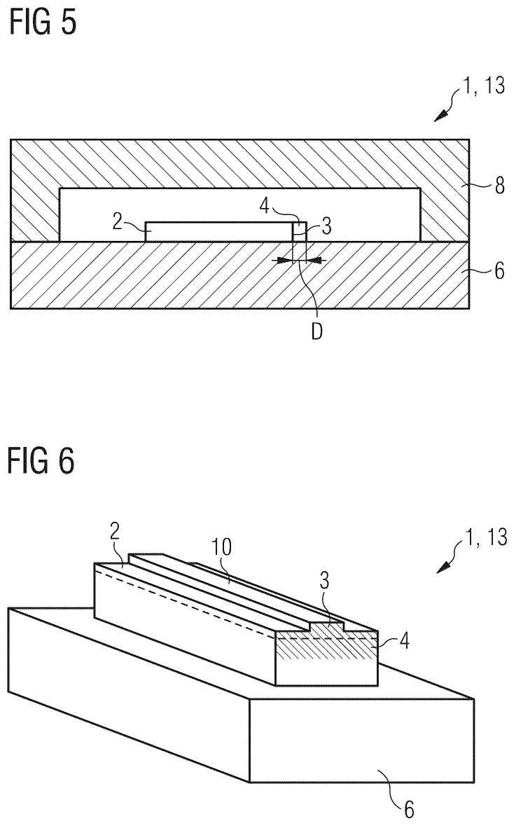

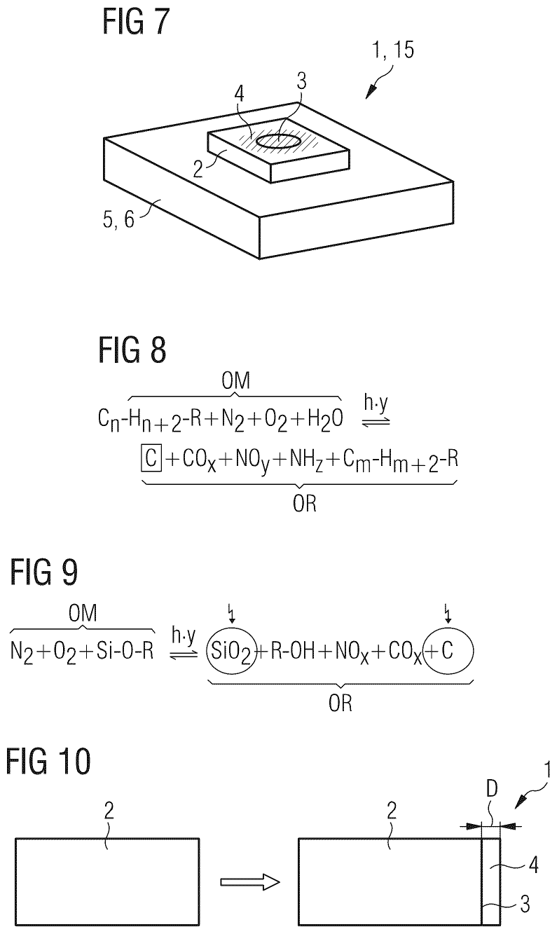

In FIG. 6 a side view of an edge-emitting semiconductor laser component according to an exemplary embodiment is shown. Here, too, a p-up configuration of the semiconductor chip 2 is shown in comparison with FIG. 3. The semiconductor chip 2 is arranged directly on the carrier 6. FIG. 7 shows a surface emitter 15 according to an exemplary embodiment. The surface emitter 15 is a VCSEL (vertical-cavity surface-emitting laser). The surface emitter is a laser diode in which the electromagnetic primary radiation is emitted perpendicular to the plane of the semiconductor chip 2. This means that the coupling-out facet 3 is parallel to the plane of the semiconductor chip 2. The functional layer 4 is arranged on the coupling-out facet 3. The semiconductor chip 2 is arranged on the carrier 6. Optionally, the semiconductor chip 2 can be arranged on the step 5.

The reaction equation shown in FIG. 8 indicates an equilibrium between volatile molecules OM and solid compounds OR. A reaction, initiated by the electromagnetic primary radiation of the semiconductor chip 2, takes place. The volatile molecules OM CₙHₙ₊₂—R+N₂+O₂+H₂O react to form elemental C, COₓ, NO_{y}, NH_{z} and Cₘ—Hₘ₊₂—R.

n, x, y, z and m are natural numbers between 1 and 20 inclusive.

Due to the functional layer 4 the equilibrium of the reaction can be shifted towards the volatile molecules OM at the coupling-out facet 3. The solid compounds OR react to form the gaseous, highly volatile molecules OM. With advantage, this prevents molecules, for example carbon compounds, from reacting on the coupling-out facet 3 to form non-volatile, solid compounds OR, settling there and thus leading to overheating of the optoelectronic component 1 and damaging the optoelectronic component 1 as a result.

In FIG. 9 a reaction equilibrium between volatile molecules OM and solid compounds OR is shown. Here, too, the equilibrium is shifted to the side of the volatile compounds OM by the functional layer. Thus, among other things it is prevented that the solid compound OR SiO₂ and C are settled on the coupling-out facet. R here stands for an organic residue, for example a residue containing carbon and optionally functional groups. X is a natural number between 1 and 3 inclusive.

The reaction equations of FIGS. 8 and 9 are not balanced.

In FIG. 10 a method for producing an optoelectronic component 1 according to an exemplary embodiment is described. First, the semiconductor chip 2 is provided. Then, the functional layer 4 is applied to the coupling-out facet 3 at least in places. The functional layer 4 may be vapor deposited or sputtered onto the coupling-out facet 3, or may be deposited via a chemical vapor deposition method, a plasma-assisted chemical vapor deposition method, or a SAM method. Hereby, the functional layer 4 is applied directly to the coupling-out facet 3.

The features and exemplary embodiments described in connection with the figures can be combined with each other according to further exemplary embodiments, even if not all combinations are explicitly described. Furthermore, the exemplary embodiments described in connection with the figures may alternatively or additionally comprise further features according to the description in the general part.

This patent application claims priority to German patent application 102020127450.5, the disclosure content of which is hereby incorporated by reference.

The invention is not limited to the exemplary embodiments by the description thereof. Rather, the invention encompasses any new feature as well as any combination of features, which in particular includes any combination of features in the patent claims, even if that feature or combination itself is not explicitly stated in the patent claims or exemplary embodiments.

1. An optoelectronic component with
a semiconductor chip, comprising,
a coupling-out facet which emits electromagnetic primary radiation during operation,
a functional layer, wherein
the coupling-out facet is covered by the functional layer at least in places,
the functional layer is a catalytic layer, and
the functional layer comprises a material selected from the following group: platinum, vanadium, molybdenum, titanium, tungsten, tantalum, palladium, FeN₄ complexes.

2. The optoelectronic component according to claim 1,
wherein the functional layer is configured to shift a reaction equilibrium from volatile molecules to solid compounds to the side of the volatile molecules.

3. The optoelectronic component according to claim 1,
wherein the volatile molecules are gaseous.

4. The optoelectronic component according to claim 1,
wherein the functional layer comprises a polyoxometalate or consists of a polyoxometalate.

5. The optoelectronic component according to claim 1,
wherein the functional layer comprises a metal compound or consists of a metal compound.

6. (canceled)

7. The optoelectronic component according to claim 1,
wherein the coupling-out facet is completely covered by the functional layer.

8. The optoelectronic component according to claim 1,
wherein the semiconductor chip comprises an active region and a waveguide and at least the active region and/or the waveguide at the coupling-out facet is completely covered by the functional layer.

9. The optoelectronic component according to claim 1,
wherein the functional layer is in direct contact with the coupling-out facet.

10. The optoelectronic component according to claim 1,
wherein the functional layer comprises a thickness of at most 5000 nanometers.

11. The optoelectronic component according to claim 1,
wherein the functional layer is formed as a monolayer.

12. The optoelectronic component according to claim 1,
wherein the optoelectronic component is an edge-emitting semiconductor laser component.

13. The optoelectronic component according to claim 1,
wherein the optoelectronic component is a surface emitter.

14. The optoelectronic component according to claim 1,
wherein the optoelectronic component is a superluminescent diode.

15. The optoelectronic component according to claim 1,
wherein the semiconductor chip emits electromagnetic radiation of a wavelength range of less than 500 nanometers during operation.

16. The optoelectronic component according to claim 1,
wherein the optoelectronic component is free of a hermetic housing.

17. A method for producing an optoelectronic component according to claim 1, the method comprising
providing the semiconductor chip
applying the functional layer at least in places to the coupling-out facet.

18. The method of producing an optoelectronic component according to claim 17,
wherein the functional layer is vapor deposited or sputtered onto the coupling-out facet or is deposited via a chemical vapor deposition, a plasma-enhanced chemical vapor deposition, or a SAM method.
